(19) United States
(12) Patent Application Publication
(10) Pub. No.: US 2023/0105710 A1
(43) Pub. Date: Apr. 6, 2023

(54) METHOD OF MANUFACTURING SEMICONDUCTOR DEVICE

(71) Applicant: SAMSUNG ELECTRONICS CO., LTD., Suwon-si (KR)

(72) Inventors: Hyekyoung Lee, Suwon-si (KR); Seungboo Jung, Seoul (KR); Taegyu Kang, Asan-si (KR); Kyungdeuk Min, Suwon-si (KR); Namyong Oh, Cheonan-si (KR); Jaeseon Hwang, Asan-si (KR); Donggil Kang, Yongin-si (KR); Eun Ha, Suwon-si (KR); Haksan Jeong, Seoul (KR)

(73) Assignee: SAMSUNG ELECTRONICS CO., LTD., Suwon-si (KR)

(21) Appl. No.: 17/954,509

(22) Filed: Sep. 28, 2022

(30) Foreign Application Priority Data
Sep. 29, 2021 (KR) 10-2021-0128952

(51) Int. Cl. H01L 23/00; H01L 25/16

(52) U.S. Cl. CPC H01L 24/81; H01L 24/11; H01L 24/13; H01L 24/16; H01L 25/16; H01L 2224/1132; H01L 2224/8122; H01L 2224/11001; H01L 2224/13111; H01L 2224/13113; H01L 2224/13139; H01L 2224/13147; H01L 2224/16245; H01L 2224/81005; H01L 2224/81007; H01L 2224/81801; H01L 2924/1431; H01L 2924/1434; H01L 2924/19041

(57) ABSTRACT

A method of manufacturing a semiconductor device includes arranging a mask on a support. The mask includes a first area and a second area. A substrate is arranged on the mask. The substrate has a mounting area and a non-mounting area. A solder paste is applied on the mounting area of the substrate. After applying the solder paste, at least one electronic device is arranged on the mounting area. A light soldering process is performed by emitting light on the substrate from a light source above the substrate. The first area of the mask is positioned under the non-mounting area and the second area of the mask is positioned under the mounting area.

### CROSS-REFERENCE TO RELATED APPLICATION

This application claims priority under 35 U.S.C. §119 to Korean Patent Application No. 10-2021-0128952, filed on Sep. 29, 2021 in the Korean Intellectual Property Office, the disclosure of which is incorporated by reference in its entirety herein.

### TECHNICAL FIELD

The present inventive concept relates to a method of manufacturing a semiconductor device. More particularly, the present inventive concept relates to a semiconductor device manufacturing method capable of preventing thermal damage to a semiconductor device and increasing the lifespan of a semiconductor device manufacturing facility.

### DISCUSSION OF RELATED ART

The demand for high-performance semiconductors has increased as the electronic industry has rapidly developed. Various devices have been mounted on semiconductor devices in response to such demand. Accordingly, various methods such as wire bonding and soldering have been used for mounting devices on semiconductor devices. In embodiments in which soldering is used, elements are mounted on a semiconductor device by applying heat to solder by using a heat source such as hot air current or a laser.

### SUMMARY

Embodiments of the present inventive concept provide a semiconductor device manufacturing method capable of preventing damage to a semiconductor device and increasing the reliability of the semiconductor device.

According to an embodiment of the present inventive concept, a method of manufacturing a semiconductor device includes arranging a mask on a support. The mask includes a first area and a second area. A substrate is arranged on the mask. The substrate has a mounting area and a non-mounting area. A solder paste is applied on the mounting area of the substrate. After applying the solder paste, at least one electronic device is arranged on the mounting area. A light soldering process is performed by emitting light on the substrate from a light source above the substrate. The first area of the mask is positioned under the non-mounting area and the second area of the mask is positioned under the mounting area.

According to an embodiment of the present inventive concept, a method of manufacturing a semiconductor device includes arranging a mask on a support. The mask includes a first area and a second area. A substrate is arranged on the mask. The substrate has a mounting area and a non-mounting area. A solder paste is applied on the mounting area of the substrate. After applying the solder paste, at least one electronic device is arranged on the mounting area. A cover layer is applied on a portion of the substrate. A light soldering process is performed by emitting light on the substrate from a light source above the substrate. The first area of the mask is positioned under the non-mounting area, and the second area is positioned under the mounting area.

According to an embodiment of the present inventive concept, a method of manufacturing a semiconductor device includes arranging a mask on a support. The mask includes a first area and a second area. A substrate is pre-heated. The substrate has a mounting area and a non-mounting area. The substrate is transported onto the mask. A solder paste is applied on the mounting area of the substrate. After applying the solder paste, at least one electronic device is arranged on the mounting area. A light soldering process is performed by emitting light on the substrate from a light source above the substrate. The first area of the mask is positioned under the non-mounting area, and the second area of the mask is positioned under the mounting area.

### BRIEF DESCRIPTION OF THE DRAWINGS

Embodiments of the present inventive concept will be more clearly understood from the following detailed description taken in conjunction with the accompanying drawings in which:

FIG. 1 is a flowchart illustrating a method of manufacturing a semiconductor device, according to an embodiment of the present inventive concept;

FIGS. 2A to 2E are cross-sectional views respectively illustrating operations of a method of manufacturing a semiconductor device, according to embodiments of the present inventive concept;

FIG. 3 is a top plan view illustrating a result of a soldering process according to a difference between thermal conductivities of mask materials;

FIGS. 4A and 4B are magnified views of a region E of FIG. 2B according to an embodiment of the present inventive concept;

FIG. 5A is a flowchart illustrating a method of manufacturing a semiconductor device, according to an embodiment of the present inventive concept;

FIG. 5B is a conceptual cross-sectional view illustrating operation S230 of the method of manufacturing a semiconductor device, according to an embodiment of the present inventive concept;

FIG. 6A is a flowchart illustrating a method of manufacturing a semiconductor device, according to an embodiment of the present inventive concept;

FIG. 6B is a conceptual cross-sectional view illustrating operation S320 of the method of manufacturing a semiconductor device, according to an embodiment of the present inventive concept; and

FIG. 6C is a conceptual cross-sectional view illustrating operation S331 of the method of manufacturing a semiconductor device, according to an embodiment of the present inventive concept.

### DETAILED DESCRIPTION OF EMBODIMENTS

Hereinafter, embodiments of the present inventive concept are described in detail with reference to the accompanying drawings. Like reference numerals in the drawings denote like elements, and thus, their repetitive description is omitted.

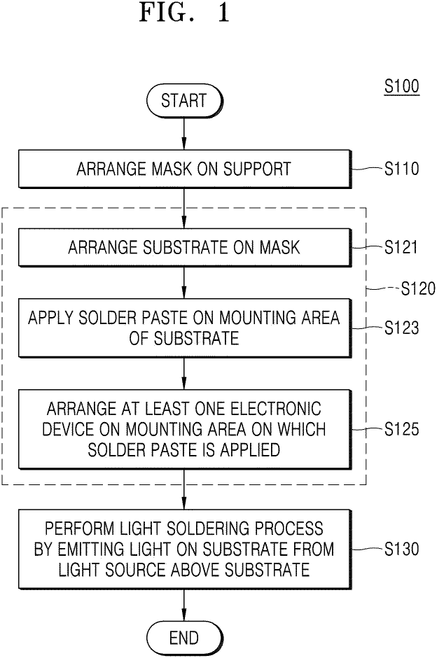

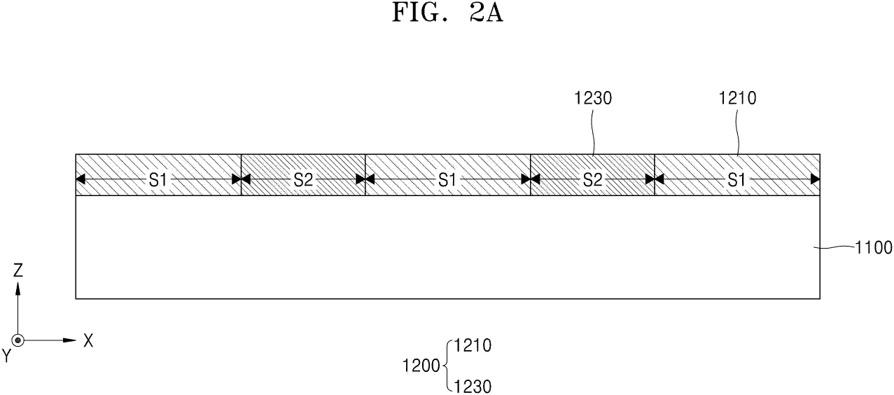

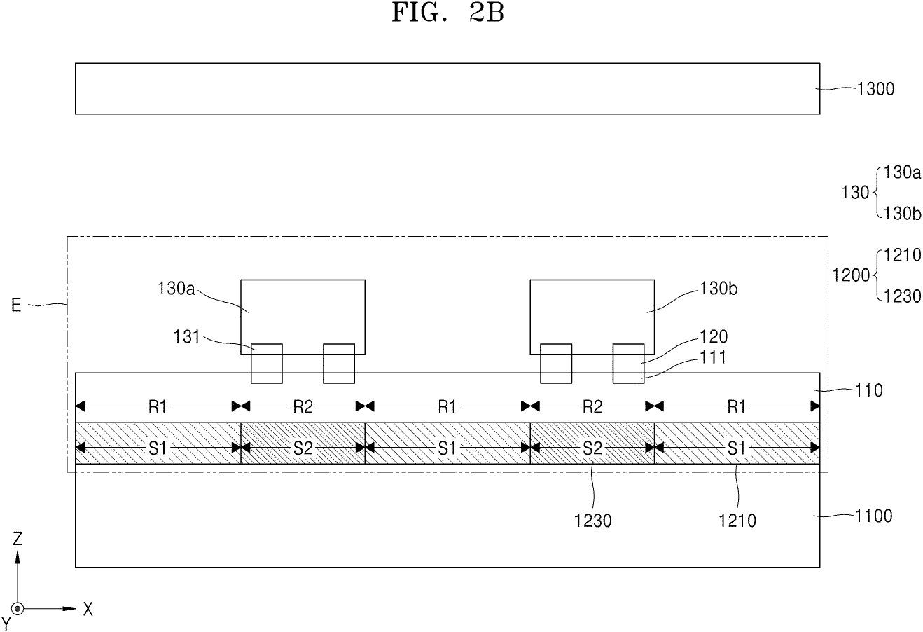

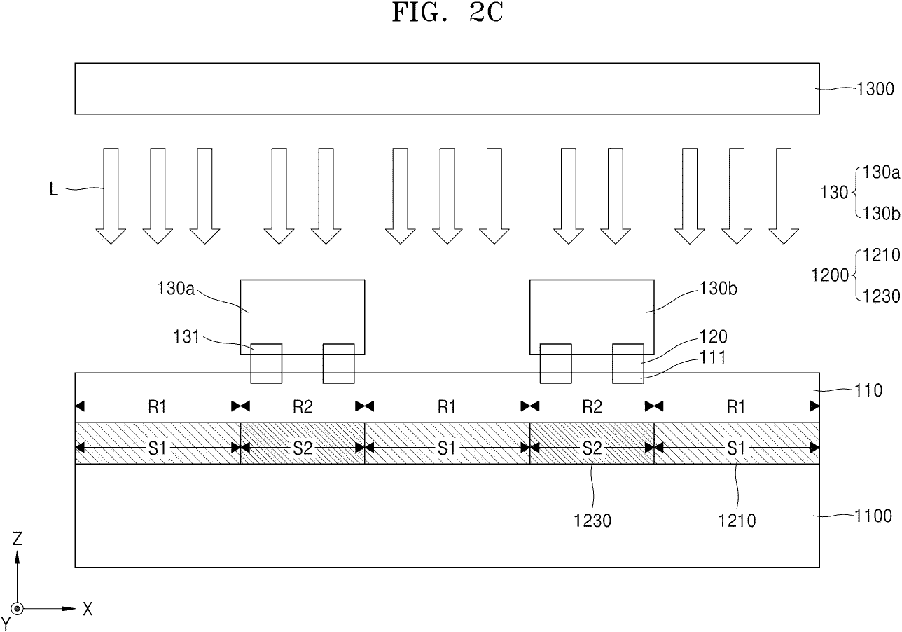

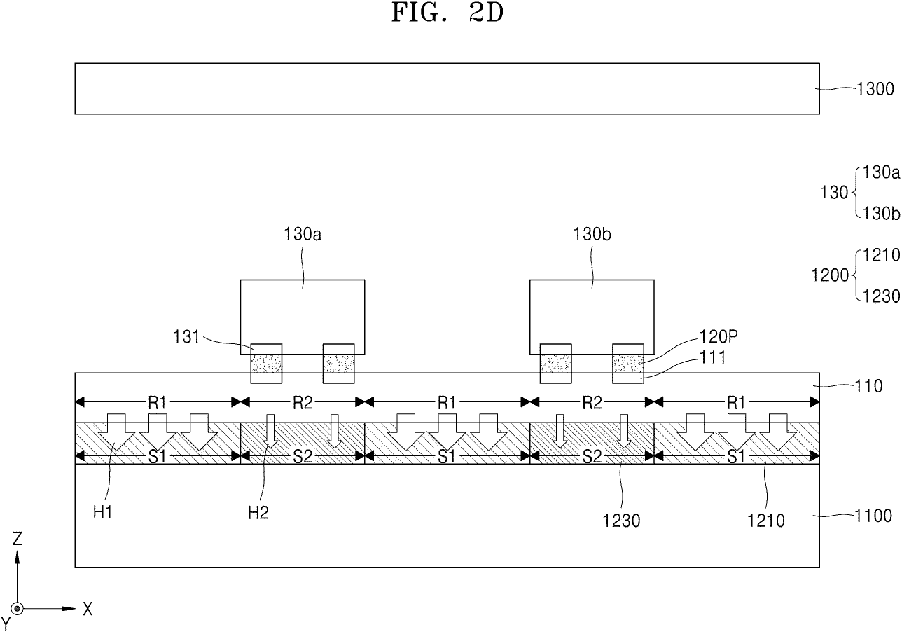

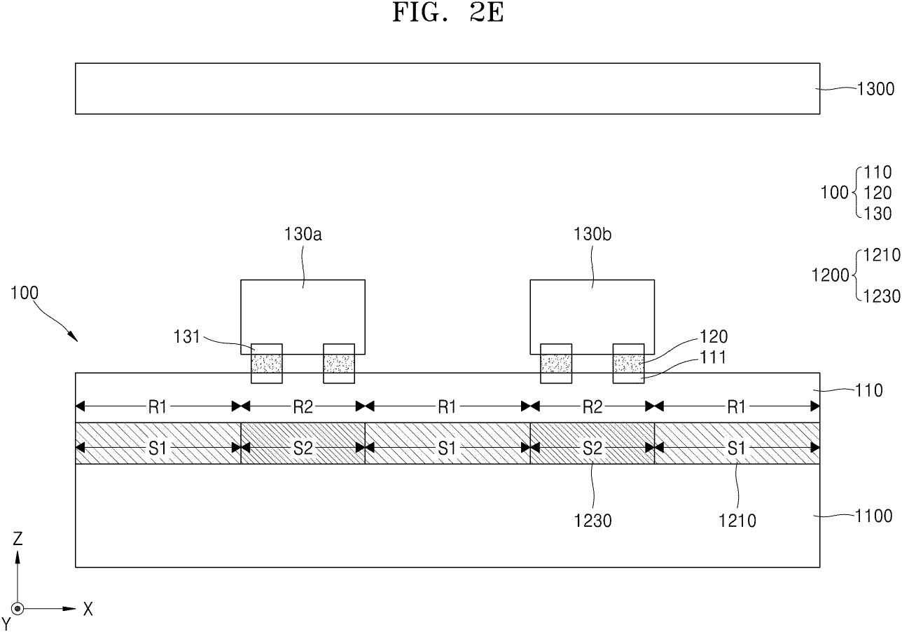

FIG. 1 is a flowchart illustrating a method S100 for manufacturing a semiconductor device, according to an embodiment of the present inventive concept. FIGS. 2A to 2E are cross-sectional views respectively illustrating operations of a method of manufacturing a semiconductor device, according to embodiments of the present inventive concept.

Referring to embodiments shown in FIGS. 1 and 2A, a mask 1200 may be arranged on a support 1100 in operation S110. In an embodiment, the support 1100 and the mask 1200 may be parallel to each other in a horizontal direction. In an embodiment, a length of the support 1100 in a first horizontal direction (e.g, an X direction) and a length of the support 1100 in a second horizontal direction (e.g., a Y direction) may be greater than or equal to a length of the mask 1200 in the first horizontal direction (e.g., the X direction) and a length of the mask 1200 in the second horizontal direction (e.g., the Y direction), respectively. Herein, the first horizontal direction indicates an X-axis direction, the second horizontal direction indicates a Y-axis direction, and the first horizontal direction and the second horizontal direction are perpendicular to each other. However, embodiments of the present inventive concept are not necessarily limited thereto

In an embodiment, a lower surface of the mask 1200 may be in direct contact with an upper surface of the support 1100. The mask 1200 may extend in parallel to and along an X-Y plane. The mask 1200 may include a first area S1 and a second area S2. The first area S1 may be positioned under a non-mounting area R1 of a substrate 110 (see FIG. 2B), and the second area S2 may be positioned under a mounting area R2 of the substrate 110 (see FIG. 2B). In this embodiment, an upper surface of the first area S1 may be in direct contact with a lower surface of the non-mounting area R1, and a lower surface of the first area S1 may be in direct contact with the support 1100. In addition, an upper surface of the second area S2 may be in direct contact with a lower surface of the mounting area R2, and a lower surface of the second area S2 may be in direct contact with the support 1100. In an embodiment, a length of the first area S1 in the first horizontal direction (the X direction) and a length of the first area S1 in the second horizontal direction (the Y direction) may be substantially the same as a length of the non-mounting area R1 in the first horizontal direction (the X direction) and a length of the non-mounting area R1 in the second horizontal direction (the Y direction), respectively. A length of the second area S2 in the first horizontal direction (the X direction) and a length of the second area S2 in the second horizontal direction (the Y direction) may be the same as a length of the mounting area R2 in the first horizontal direction (the X direction) and a length of the mounting area R2 in the second horizontal direction (the Y direction), respectively. The first area S1 and the non-mounting area R1 may overlap each other in a vertical direction (a Z direction), and the second area S2 and the mounting area R2 may overlap each other in the vertical direction (the Z direction). In an embodiment, the Z direction may be perpendicular to the first horizontal direction (the X direction) and the second horizontal direction (the Y direction).

In an embodiment, the first area S1 of the mask 1200 may include a first material 1210, the second area S2 of the mask 1200 may include a second material 1230, and a thermal conductivity of the first material 1210 may be greater than a thermal conductivity of the second material 1230. For example, in an embodiment, the first material 1210 may be a material, e.g., glass or iron, having a thermal conductivity in a range of about 1 W/mk to about 43 W/mk, about 5 W/mk to 30 W/mk, or about 10 W/mk to about 20 W/mk. For example, in an embodiment, the first material 1210 may be a material having a thermal conductivity greater than or equal to about 1 W/mk. The second material 1230 may be a material having a thermal conductivity in a range of about 0.01 W/mk to about 1 W/mk. For example, the second material 1230 may be a material having a thermal conductivity that is less than or equal to about 1 W/mk. As such, because the thermal conductivity of the first material 1210 in the first area S1 is greater than the thermal conductivity of the second material 1230 in the second area S2, heat is quickly dissipated through the first area S1, whereas heat is relatively slowly dissipated through the second area S2.

In an embodiment, a length of the mask 1200 in the vertical direction (the Z direction) may be about 1 mm. However, embodiments of the present inventive concept are not limited thereto.

Referring to FIGS. 1 and 2B, the substrate 110 may be arranged on the mask 1200 in operation S121, a solder paste 120P (FIG. 2D) is applied on a plurality of first pads 111 of the mounting area R2 of the substrate 110 in operation S123, and a plurality of electronic devices 130 may be arranged on the mounting area R2, on which the solder paste 120P is applied, in operation S125.

Herein, the mounting area R2 indicates an area on the substrate 110 on which at least one electronic device 130 is arranged, and the non-mounting area R1 indicates an area on the substrate 110 which does not include at least one electronic device 130 arranged thereon.

In operation S121, the substrate 110 may be arranged on the mask 1200. In an embodiment, the substrate 110 may include a group IV semiconductor such as silicon (Si) or germanium (Ge), a group IV-IV compound semiconductor such as silicon germanium (SiGe) or silicon carbide (SiC), or a group III-V compound semiconductor such as gallium arsenide (GaAs), indium arsenide (InAs), or indium phosphide (InP). The substrate 110 may have an active surface and an inactive surface that is opposite to the active surface. A semiconductor device including various types of a plurality of individual devices may be formed on the active surface of the substrate 110. For example, in an embodiment, the plurality of individual devices may include various micro electronic devices, e.g, complementary metal-oxide semiconductor (CMOS) transistors, metal-oxide-semiconductor filed effect transistors (MOSFETs), system large scale integration (LSI) chips, image sensors such as CMOS imaging sensors (CISs), micro-electro-mechanical systems (MEMSs), active devices, passive devices, and the like.

The substrate 110 may include the plurality of first pads 111. In an embodiment, the plurality of first pads 111 may include a conductive material, for example, at least one compound selected from copper (Cu), aluminum (Al), silver (Ag), titanium (Ti), and nickel (Ni). However, embodiments of the present inventive concept are not necessarily limited thereto. Each of the plurality of first pads 111 may include the same material as each other. In an embodiment, the first pad 111 may protrude from the substrate 110 (e.g., in the Z direction). However, embodiments of the present inventive concept are not necessarily limited thereto. For example, in an embodiment, an upper surface of the first pad 111 may be coplanar with an upper surface of the substrate 110. The upper surface of the first pad 111 may be in direct contact with a lower surface of the solder paste 120P. Both side surfaces of the first pad 111 may be surrounded by the substrate 110. In an embodiment, the first pad 111 may be surface-treated by an organic solderability preservation (OSP) scheme. However, embodiments of the present inventive concept are not necessarily limited thereto. For example, the first pad 111 may be surface-treated by a scheme such as hot air solder leveling (HASL) or electroless gold plating.

The solder paste 120P may be applied on the plurality of first pads 111 on the mounting area R2 in operation S123. In an embodiment, the solder paste 120P may include a conductive material, such as at least one compound selected from Cu, tin (Sn), Ag, an alloy thereof, and an alloy thereof including bismuth (Bi). For example, the solder paste 120P may be an alloy including about 96.5 weight% of Cu, about 3.0 weight% of Sn, and about 0.5 weight% of Ag. However, embodiments of the present inventive concept are not limited thereto. In an embodiment, a volume of the solder paste 120P may be in a range of about 2.681X10⁻¹¹ m³ to about 2.681X10⁻¹² m³. However, embodiments of the present inventive concept are not necessarily limited thereto. The solder paste 120P may be applied by, for example, screen-screen printing, stencil printing, or direct-printing. However, embodiments of the present inventive concept are not necessarily limited thereto. For example, in an embodiment in which the solder paste 120P is applied by screen-printing, a metal mask including a plurality of opening portions is arranged on the substrate 110 and overlaps the substrate 110. In this embodiment, the metal mask is arranged so that the plurality of opening portions of the metal mask are aligned with the mounting area R2 of the substrate 110 in the vertical direction (e.g., the Z direction). Once the metal mask is arranged, the solder paste 120P is spread on the metal mask. Thereafter, a squeegee of a screen-printer may push the spread solder paste 120P into the plurality of opening portions of the metal mask. Through the aforementioned process, the solder paste 120P may be applied on the mounting area R2 and may not be applied onto the non-mounting area R1. In an embodiment, a thickness (e.g., a length in a vertical direction, such as the Z direction) of the opening portion of the metal mask may be in a range of about 80 um to about 100 um, and a width (e.g., a length in a horizontal direction, such as the X direction and/or the Y direction)) thereof may be about 270 um. However, embodiments of the present inventive concept are not necessarily limited thereto. A scheme of applying the solder paste 120P may vary in accordance with circumstances. For example, in an embodiment in which the solder paste 120P cannot be applied by screen-printing, such as if the pitches of electronic devices 130a and 130b are small, the solder paste 120P may be applied by stencil printing.

At least one of the electronic devices 130a and 130b may be arranged on the mounting area R2 on which the solder paste 120P is applied, in operation S125. In this embodiment, the at least one of the electronic devices 130a and 130b may be aligned so that lower surfaces of a plurality of second pads 131 are in direct contact with an upper surface of the solder paste 120P. The electronic devices 130a and 130b may be arranged by, for example, pick and place or another arbitrary scheme. Although an embodiment of FIG. 2B shows that two electronic devices 130a and 130b are arranged on the substrate 110, embodiments of the present inventive concept are not necessarily limited thereto, and for example, one electronic device may be arranged, or three or more electronic devices may be arranged.

In an embodiment, the at least one electronic device 130 may be selected from among passive devices including semiconductor chips, semiconductor packages, and multi-layer ceramic condensers (MLCCs). For example, although an embodiment of FIG. 2B shows that the electronic devices 130a and 130b are semiconductor chips, the electronic devices 130a and 130b are not necessarily limited thereto. For example, in an embodiment, the electronic device 130a may be a semiconductor chip, and the electronic device 130b may be a semiconductor package. In an embodiment in which the electronic device 130 is a semiconductor chip, the semiconductor chip may be a memory chip or a logic chip. In an embodiment, the memory chip may be, for example, a volatile memory chip such as a dynamic random access memory (DRAM) or static random access memory (SRAM) chip or a nonvolatile memory chip such as a phase-change random access memory (PRAM), magnetoresistive random access memory (MRAM), ferroelectric random access memory (FeRAM), or resistive random access memory (RRAM) chip. In addition, the logic chip may be, for example, a microprocessor, an analog device, or a digital signal processor. In an embodiment in which the electronic device 130 is a semiconductor package, the semiconductor package may be, for example, a system in package (SIP), a wafer level package (WLP), or the like The electronic device 130 may include a plurality of second pads 131. The second pad 131 may include a conductive material, for example, at least one compound selected from Cu, Al, Ag, Ti, and Ni. However, embodiments of the present inventive concept are not necessarily limited thereto. In an embodiment in which the plurality of second pads 131 are included, each of the plurality of second pads 131 may include the same material as each other. In an embodiment, a lower surface of the second pad 131 may be coplanar with a lower surface of the electronic device 130. Both side walls of the second pad 131 may be surrounded by the electronic device 130.

Referring to FIGS. 1 and 2C, a soldering process may be performed by emitting light L on the substrate 110 in operation S130. In an embodiment, the soldering process may be a light soldering process. Unlike existing reflow or laser soldering, light soldering may be applied even to a semiconductor device having a relatively large area. In addition, since light soldering uses the light L having high energy for a short time, the light soldering process may be more quickly finished than reflow or laser soldering. Therefore, by using the light soldering process, a semiconductor device may not be exposed to heat for a long period of time.

A light source 1300 may be positioned above the substrate 110. For example, the light L may be emitted in a direction from the light source 1300 toward the substrate 110. In this embodiment, since the light L is directly emitted on the substrate 110 without passing through a separate filter or mask, an energy loss of the light L due to a filter or a mask may be prevented. Therefore, the soldering process may be performed using the light L having less energy than if the light L had to pass through a filter or mask and a lifespan of the light source 1300 may be increased.

In an embodiment, the light source 1300 may be a xenon lamp. For example, the light source 1300 may be a xenon flash lamp. In an embodiment, a wavelength of the xenon flash lamp may be in a range of about 185 nm to about 2000 nm or about 400 nm to about 1200 nm.

In an embodiment, the light L may be intense pulsed light (IPL). The IPL is a short and strong pulsed light having a spectrum of a wide wavelength. The IPL may emit multi-wavelength light on a large area and selectively heat through exposure with highly intense and short pulses. In an embodiment, a frequency of the IPL may be greater than or equal to about 2 Hz. For example, the frequency of the IPL may be in a range of about 2 Hz to about 4 Hz. In an embodiment, a pulse width of the IPL may be greater than or equal to about 2 ms. For example, the pulse width of the IPL may be in a range of about 2 ms to about 4 ms. In an embodiment, the number of emission times of the IPL may be greater than or equal to about six. For example, the number of emission times of the IPL may be about six to about eight. However, the number of emission times of the IPL is not limited thereto and may vary, such as according to a constituent material of the mask 1200, a type of the solder paste 120P, and the like.

In an embodiment, the light L may be emitted all over the substrate 110. For example, the light L may be uniformly emitted all over the upper surface of the substrate 110 that is parallel to the X-Y plane.

Referring to FIG. 2D, when the light L is emitted on the substrate 110 and the electronic device 130, energy of the light L is converted into thermal energy. Arrows in FIG. 2D respectively indicate conduction of heat H1 from the non-mounting area R1 to the first area S1 of the mask 1200 and conduction of heat H2 from the mounting area R2 to the second area S2 of the mask 1200. Sizes of the arrows relatively indicate degrees of conduction of the heats H1 and H2. Since a thermal conductivity of the first material 1210 in the first area S1 is greater than a thermal conductivity of the second material 1230 in the second area S2, the heat H1 of the non-mounting area R1 is quickly dissipated through the first area S1, whereas the heat H2 of the mounting area R2 is more slowly dissipated through the second area S2 than the heat H1. Therefore, the non-mounting area R1 of the substrate 110 may be prevented from being damaged by the heat H1 by using a thermal conductivity difference between the first and second areas S1 and S2 of the mask 1200, and in the mounting area R2, a temperature of the solder paste 120P may be increased to a melting point by using the heat H2, thereby performing a light soldering process

In an embodiment, the melting point of the solder paste 120P may be in a range of about 180° C. to about 220° C. For example, the melting point of the solder paste 120P may be about 217° C.

Referring to FIG. 2E, the light soldering process may be completed by using the heat H2 (FIG. 2D) to melt the solder paste 120P on the mounting area R2 and then hardening the melted solder paste 120P. The solder paste 120P in FIG. 2D may be converted to solder 120 by the light soldering process. In an embodiment, the solder 120 may be, for example, a solder bump. However, embodiments of the present inventive concept are not necessarily limited thereto. According to the completion of the light soldering process, a semiconductor device 100 including the substrate 110, the solder 120, and the at least one electronic device 130 is manufactured.

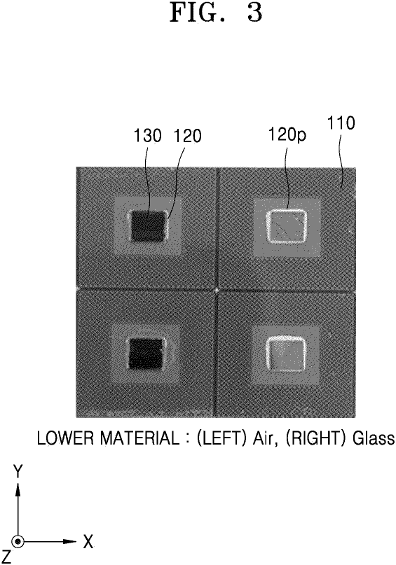

FIG. 3 is a top view illustrating a result of a soldering process according to a difference between thermal conductivities of materials of the mask 1200. A left side of FIG. 3 indicates a result of a soldering process in an embodiment in which a material in the second area S2 overlapping the mounting area R2 in the vertical direction is air, and a right side of FIG. 3 indicates, as a comparative example, a result of a soldering process in which the material in the second area S2 overlapping the mounting area R2 in the vertical direction is glass.

Referring to FIG. 3, in an embodiment on the left side that uses air having a thermal conductivity of about 0.026 W/mk as the mask 1200, heat is not easily dissipated because the thermal conductivity of the mask 1200 is relatively low. Therefore, a soldering process using heat may be performed. In this embodiment, the solder paste 120P applied on the mounting area R2 in the horizontal direction coheres to be converted into the solder 120, and the solder 120 cannot maintain horizontality Therefore, light is diffuse-reflected by the solder 120 which cannot maintain horizontality, and thus, the mounting area R2 is not viewed. Alternatively, in a comparative embodiment of the right side that uses a mask 1200 comprised of glass having a thermal conductivity in a range of about 1 W/mk to about 1.1 W/mk, heat is easily dissipated because the thermal conductivity of the mask 1200 is relatively high. Therefore, the heat that is provided is not sufficient to perform a soldering process. In this comparative embodiment, the solder paste 120P applied on the mounting area R2 in the horizontal direction is not converted to the solder 120 and may still maintain horizontality. Therefore, light is reflected from the solder paste 120P, and thus, the mounting area R2 may be viewed.

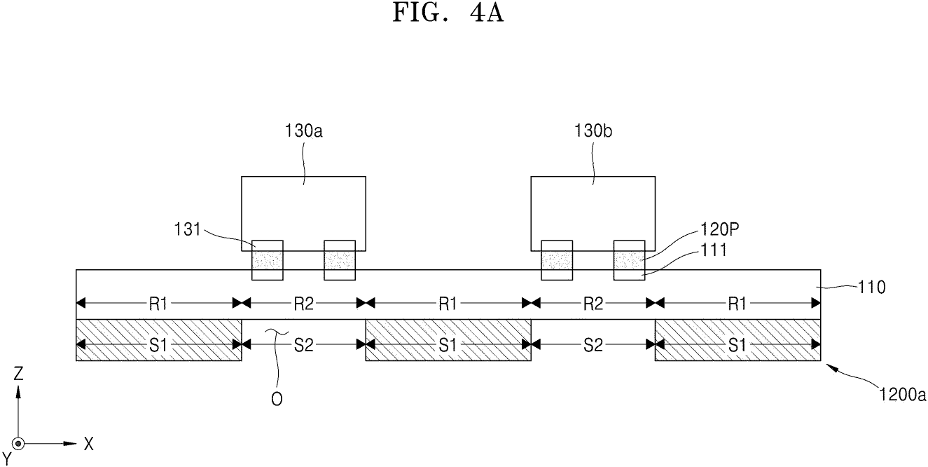

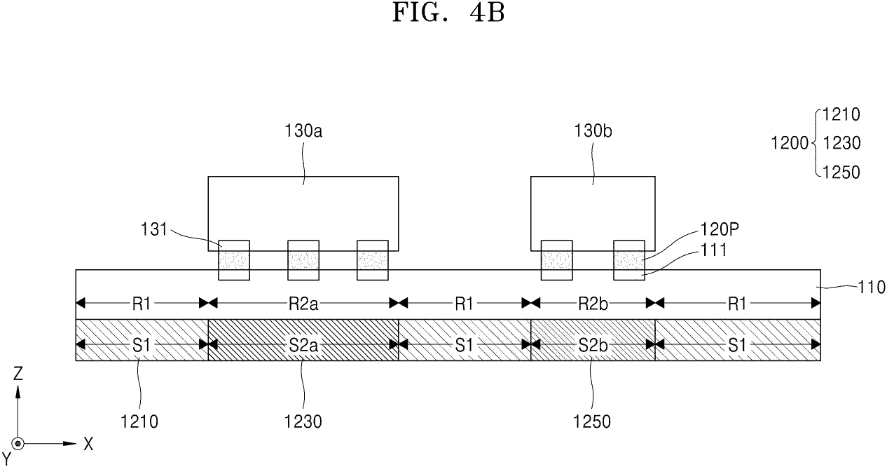

FIGS. 4A and 4B are magnified views of a region E of FIG. 2B.

Referring to FIG. 4A, a mask 1200a may include an opening portion O under the mounting area R2 of the substrate 110. For example, a material of the mask 1200a may be positioned under the non-mounting area R1, and the opening portion O may be positioned under the mounting area R2. A length of the material of the mask 1200a in the first horizontal direction (the X direction) and a length of the material of the mask 1200a in the second horizontal direction (the Y direction) may be the same as the length of the non-mounting area R1 in the first horizontal direction (the X direction) and the length of the non-mounting area R1 in the second horizontal direction (the Y direction), respectively. A length of the opening portion O in the first horizontal direction (the X direction) and a length of the opening portion O in the second horizontal direction (the Y direction) may be the same as the length of the mounting area R2 in the first horizontal direction (the X direction) and the length of the mounting area R2 in the second horizontal direction (the Y direction), respectively. Both side walls of the opening portion O may be surrounded by the material of the mask 1200a. In this embodiment, air in the opening portion O acts as the mask 1200a.

In an embodiment, a thermal conductivity of the material of the mask 1200a may be greater than a thermal conductivity of the opening portion O, such as the air. For example, the thermal conductivity of the material of the mask 1200a may be in a range of about 1 W/mk to about 43 W/mk, about 5 W/mk to about 30 W/mk, or about 10 W/mk to about 20 W/mk. For example, the material of the mask 1200a may have a thermal conductivity greater than or equal to about 1 W/mk.

Referring to an embodiment of FIG. 4B, a mask 1200b may include the first area S1 and the second area S2, and the second area S2 may include a first sub-area S2a and a second sub-area S2b. In this embodiment, the first area S1 may be positioned under the non-mounting area R1, the first sub-area S2a may be positioned under a first mounting area R2a, and the second sub-area S2b may be under a second mounting area R2b that is spaced apart from the first mounting area R2a.

The first area S1 may include the first material 1210, the first sub-area S2a may include the second material 1230, and the second sub-area S2b may include a third material 1250. The first material 1210, the second material 1230, and the third material 1250 may have different thermal conductivities from each other

In an embodiment, the thermal conductivity of the first material 1210 may be in a range of about 1 W/mk to about 43 W/mk, about 5 W/mk to about 30 W/mk, or about 10 W/mk to about 20 W/mk, and the thermal conductivities of the second material 1230 and the third material 1250 may be different from each other and in a range of about 0.01 W/mk to about 1 W/mk. For example, in an embodiment, the thermal conductivity of the first material may be greater than or equal to about 1 W/mk and the thermal conductivities of the second and third materials 1230, 1250 may be less than or equal to about 1 W/mk. For example, when the electronic device 130a mounted on the first mounting area R2a on the first sub-area S2a including the second material 1230 has a larger area than the electronic device 130b mounted on the second mounting area R2b on the second sub-area S2b including the third material 1250, the thermal conductivity of the second material 1230 may be less than the thermal conductivity of the third material 1250. In an embodiment, when a volume of the solder paste 120P applied on the first mounting area R2a is greater than a volume of the solder paste 120P applied on the second mounting area R2b, the thermal conductivity of the second material 1230 may be less than the thermal conductivity of the third material 1250.

A length of the first sub-area S2a in the first horizontal direction (the X direction) and a length of the first sub-area S2a in the second horizontal direction (the Y direction) may differ from a length of the second sub-area S2b in the first horizontal direction (the X direction) and a length of the second sub-area S2b in the second horizontal direction (the Y direction), respectively. For example, when the electronic device 130a mounted on the first mounting area R2a has a larger area than the electronic device 130b mounted on the second mounting area R2b, a length of the first mounting area R2a in the first horizontal direction (the X direction) is greater than a length of the second mounting area R2b in the first horizontal direction (the X direction). Accordingly, the length of the first sub-area S2a positioned under the first mounting area R2a, in the first horizontal direction (the X direction) may be greater than the length of the second sub-area S2b, positioned under the second mounting area R2b, in the first horizontal direction (the X direction).

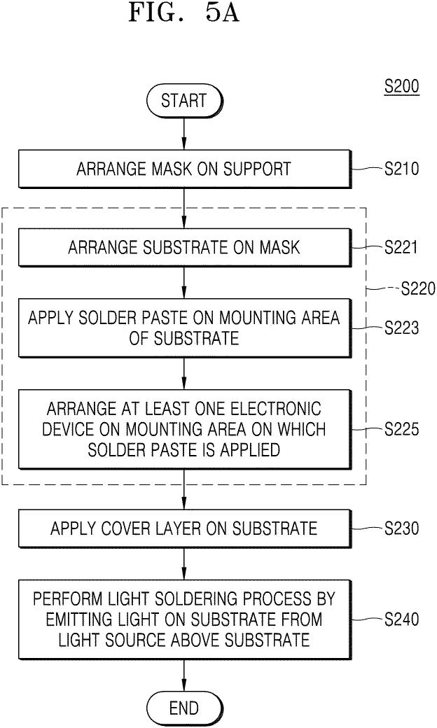

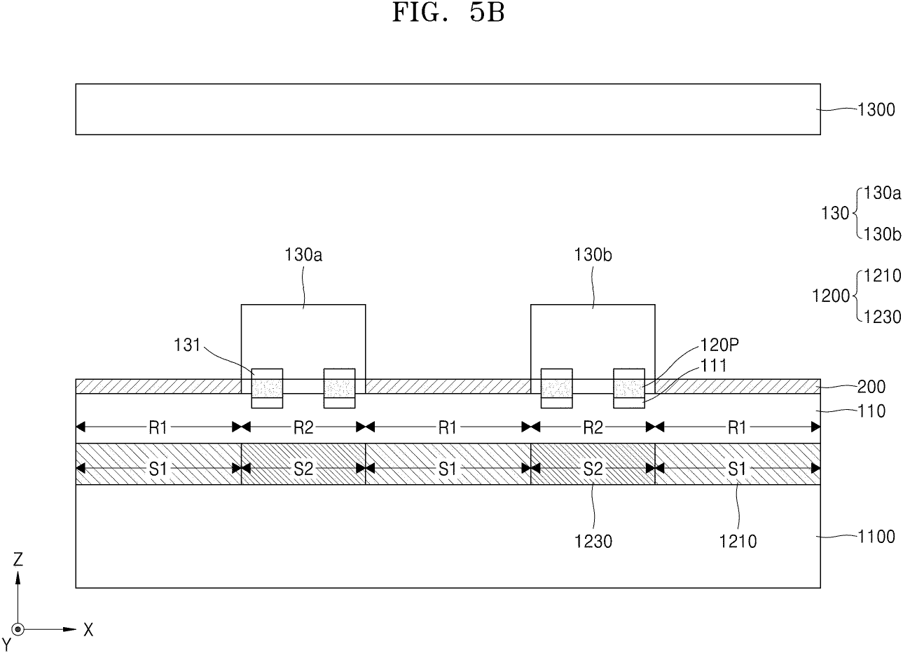

FIG. 5A is a flowchart illustrating a method S200 for manufacturing a semiconductor device, according to an embodiment of the present inventive concept. FIG. 5B is a conceptual diagram illustrating operation S230 of the method S200 for manufacturing a semiconductor device, according to an embodiment of the present inventive concept. In the method S200 for manufacturing a semiconductor device, operations S210, S220, and S240 are the same as operations S110, S120, and S130 described with reference to FIGS. 1 and 2A to 2E, respectively, and thus, hereinafter operation S230 is mainly described.

Referring to FIGS. 5A and 5B, a cover layer 200 may be arranged on the non-mounting area R1 of the substrate 110 in operation S230. In an embodiment, the cover layer 200 may be solely arranged on the non-mounting area R1 of the substrate 110 and may not be arranged on the mounting area R2 of the substrate 110.

In an embodiment, the cover layer 200 may include a material that reflects the light L (see FIG. 2C). For example, in an embodiment, the cover layer 200 may have a color, eg., white, that reflects the light L. Although an embodiment of FIG. 5B shows that the cover layer 200 includes a single layer, embodiments of the present inventive concept are not necessarily limited thereto. For example, the cover layer 200 may include a plurality of layers, and the plurality of layers may include different materials, respectively. A length of the cover layer 200 in the first horizontal direction (the X direction) may be the same as the length of the non-mounting area R1 in the first horizontal direction (the X direction). The cover layer 200 may reflect the light L to prevent the non-mounting area R1 of the substrate 110 from being damaged by heat due to the light L.

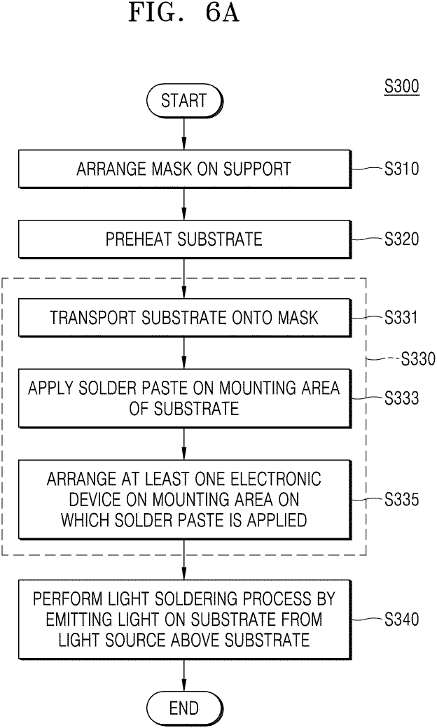

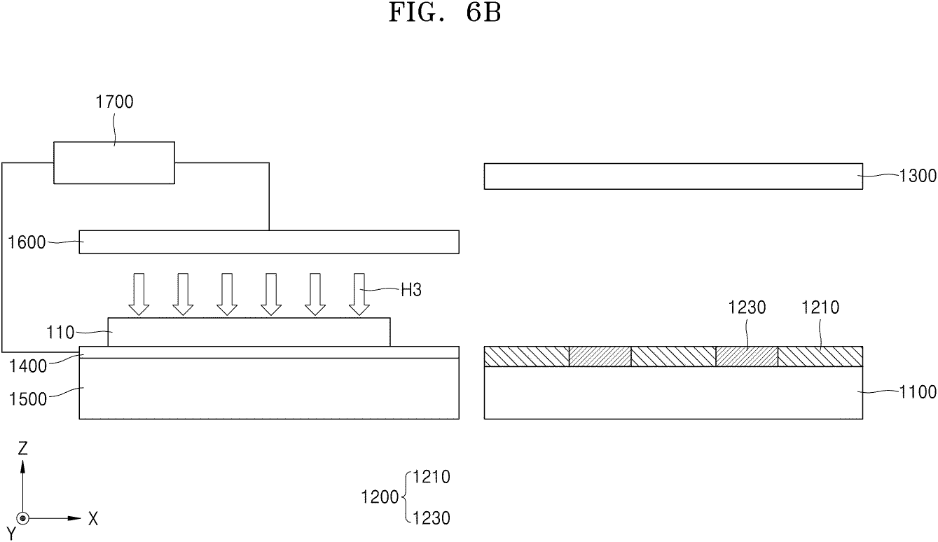

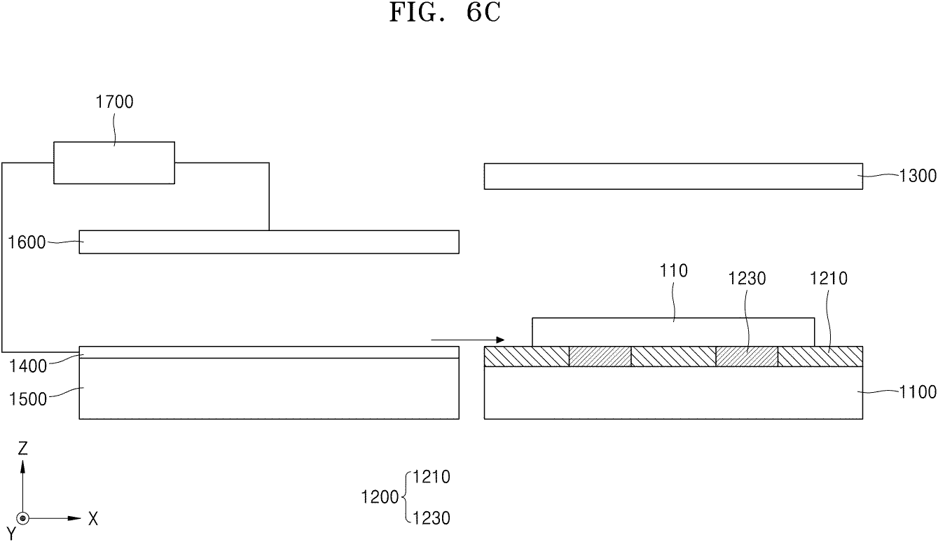

FIG. 6A is a flowchart illustrating a method S300 for manufacturing a semiconductor device, according to an embodiment of the present inventive concept. FIG. 6B is a conceptual cross-sectional view illustrating operation S320 of the method S300 for manufacturing a semiconductor device, according to an embodiment of the present inventive concept. FIG. 6C is a conceptual cross-sectional view illustrating operation S331 of the method S300 for manufacturing a semiconductor device, according to an embodiment of the present inventive concept. In the method S300 for manufacturing a semiconductor device, operations S310, S333, S335, and S340 are the same as operations S110, S123, S125, and S130 described with reference to FIGS. 1 and 2A to 2E, respectively, and thus, hereinafter operations S320 and S331 are mainly described and repeated description of similar or identical operations and/or elements may be omitted for convenience of explanation.

Referring to FIGS. 6A and 6B, operation S320 may include: arranging the substrate 110 on a pre-heater support 1500; and pre-heating the substrate 110 by a pre-heater 1600. In an embodiment, the substrate 110 may be arranged on the pre-heater support 1500 to be parallel in the horizontal direction.

In an embodiment, the pre-heater 1600 may be above the pre-heater support 1500 so as to be aligned with the pre-heater support 1500 in the vertical direction (the Z direction). The pre-heater 1600 may uniformly radiate heat H3 on the substrate 110. The pre-heater 1600 may be, for example, a heater using near-infrared (NIR) rays. However, embodiments of the present inventive concept are not necessarily limited thereto, and any arbitrary other heater may be used instead of or in addition to the heater that uses NIR rays. In an embodiment in which the pre-heater 1600 is an NIR heater, a wavelength of an NIR ray may be in a range of about 0.7 um to about 2 um or about 0.8 um to about 1.4 um. The pre-heater 1600 may preheat the substrate 110 in a range of about 30° C. to about 70° C., e.g., about 50° C. A temperature of the substrate 110 may be increased by preheating the substrate 110, and accordingly, a light soldering process may be performed by emitting the light L of a lower energy as compared to an embodiment in which the substrate 110 is not preheated. In this embodiment, the lifespan of the light source 1300 may increase. An operation of the pre-heater 1600 may be controlled by a controller 1700. The pre-heater 1600 may be configured to transmit and receive electrical signals to and from the controller 1700.

Referring to FIGS. 6A to 6C, a transporter 1400 may transport the preheated substrate 110 onto the mask 1200 on the support 1100. In an embodiment, the transporter 1400 may be, for example, a conveyor belt positioned on the pre-heater support 1500. However, embodiments of the present inventive concept are not necessarily limited thereto. For example, in an embodiment, the transporter 1400 may be a sliding carrier. An operation of the transporter 1400 may be controlled by the controller 1700. The transporter 1400 may be configured to transmit and receive electrical signals to and from the controller 1700.

The controller 1700 may control operations of the transporter 1400 and the pre-heater 1600. For example, the controller 1700 may be configured to transmit and receive electrical signals to and from the transporter 1400 and the pre-heater 1600 and may be configured to control an operation of the transporter 1400 through the signal transmission and reception.

In an embodiment, the controller 1700 may be implemented by hardware, firmware, software, or any combination thereof For example, the controller 1700 may be a computing device such as a workstation computer, a desktop computer, a laptop computer, or a tablet computer. For example, the controller 1700 may include memory devices such as read-only memory (ROM) and random access memory (RAM), processors, e.g., a microprocessor, a central processing unit (CPU), and a graphics processing unit (GPU), configured to perform certain computations and algorithms, and the like. In addition, the controller 1700 may include a receiver and a transmitter configured to receive and transmit electrical signals.

In an embodiment, after arranging the substrate 110 on the mask 1200 by the transporter 1400, an additional alignment process may be performed. In this embodiment, the substrate 110 may be arranged so that the non-mounting area R1 and the first area S1 are aligned in the vertical direction (the Z direction), and the mounting area R2 and the second area S2 are aligned in the vertical direction (the Z direction).

While the present inventive concept has been particularly shown and described with reference to non-limiting embodiments thereof, it will be understood that various changes in form and details may be made therein without departing from the spirit and scope of the present inventive concept.

What is claimed is:

1. A method of manufacturing a semiconductor device, the method comprising:
arranging a mask on a support, the mask including a first area and a second area;
arranging a substrate on the mask, the substrate having a mounting area and a non-mounting area;
applying a solder paste on the mounting area of the substrate;
after applying the solder paste, arranging at least one electronic device on the mounting area; and
performing a light soldering process by emitting light on the substrate from a light source above the substrate,
wherein the first area of the mask is positioned under the non-mounting area and the second area of the mask is positioned under the mounting area.

2. The method of claim 1, wherein:
the mask includes a first material in the first area and a second material in the second area; and
a thermal conductivity of the first material is greater than a thermal conductivity of the second material.

3. The method of claim 2, wherein:
the thermal conductivity of the first material is greater than or equal to about 1 W/mk; and
the thermal conductivity of the second material is less than or equal to about 1 W/mk.

4. The method of claim 1, wherein:
the second area includes a first sub-area and a second sub-area;
the first area includes a first material;
the first sub-area and the second sub-area include a second material and a third material, respectively; and
the first material, the second material, and the third material have different thermal conductivities from each other.

5. The method of claim 4, wherein:
the thermal conductivity of the first material is greater than or equal to about 1 W/mk; and
the thermal conductivities of the second and third materials are less than or equal to about 1 W/mk.

6. The method of claim 1, wherein the mask comprises an opening portion in the second area.

7. The method of claim 6, wherein a thermal conductivity of a material of the mask is greater than or equal to about 1 W/mk.

8. The method of claim 1, wherein the light is intense pulsed light (IPL).

9. The method of claim 8, wherein a frequency of the IPL is greater than or equal to about 2 Hz.

10. The method of claim 8, wherein a pulse width of the IPL is greater than or equal to about 2 ms.

11. The method of claim 8, wherein a number of emission times of the IPL is greater than or equal to about 6.

12. The method of claim 1, wherein a melting point of the solder paste is in a range of about 180° C. to about 220° C.

13. The method of claim 1, wherein the solder paste may include a compound selected from copper (Cu), tin (Sn), silver (Ag), an alloy thereof and an alloy thereof including bismuth (Bi).

14. The method of claim 1, wherein the at least one electronic device comprises a passive device independently selected from a semiconductor chip, a semiconductor package, and a multi-layer ceramic condenser (MLCC).

15. A method of manufacturing a semiconductor device, the method comprising:
arranging a mask on a support, the mask including a first area and a second area;
arranging a substrate on the mask, the substrate having a mounting area and a non-mounting area;
applying a solder paste on the mounting area of the substrate;
after applying the solder paste, arranging at least one electronic device on the mounting area; applying a cover layer on a portion of the substrate; and
performing a light soldering process by emitting light on the substrate from a light source above the substrate,
wherein the first area of the mask is positioned under the non-mounting area, and the second area is positioned under the mounting area.

16. The method of claim 15, wherein the cover layer comprises a light reflective material.

17. The method of claim 15, wherein the cover layer is applied on the non-mounting area.

18. The method of claim 15, wherein the light is uniformly emitted all over the substrate.

19. A method of manufacturing a semiconductor device, the method comprising:
arranging a mask on a support, the mask including a first area and a second area;
preheating a substrate having a mounting area and a non-mounting area;
transporting the substrate onto the mask;
applying a solder paste on the mounting area of the substrate;
after applying the solder paste, arranging at least one electronic device on the mounting area; and
performing a light soldering process by emitting light on the substrate from a light source above the substrate,
wherein the first area of the mask is positioned under the non-mounting area, and the second area of the mask is positioned under the mounting area.

20. The method of claim 19, further comprising aligning the substrate transported onto the mask so that the mounting area of the substrate overlaps the second area of the mask in a vertical direction.
